(19) United States
(12) Patent Application Publication
(10) Pub. No.: US 2025/0244527 A1
(43) Pub. Date: Jul. 31, 2025

(54) Integrated Memory Device with Optical Link

(71) Applicant: Taiwan Semiconductor Manufacturing Company, Ltd., Hsin-Chu (TW)

(72) Inventors: Tso-Jung Chang, Taoyuan City (TW); Chih-Peng Lin, Hsinchu County (TW); Jeng-Shien Hsieh, Kaohsiung (TW); Chieh-Yen Chen, Taipei City (TW); Hung-Yi Kuo, Taipei City (TW); Han-Jong Chia, Hsinchu City (TW)

(21) Appl. No.: 18/650,382

(22) Filed: Apr. 30, 2024

Related U.S. Application Data
(60) Provisional application No. 63/626,345, filed on Jan. 29, 2024.

(51) Int. Cl. G02B 6/12; G02B 6/13; H01L 25/16; H10B 80/00

(52) U.S. Cl. CPC G02B 6/12004; G02B 6/12007; G02B 6/13; H01L 25/167; H10B 80/00

(57) ABSTRACT

The present disclosure provides an integrated circuit (IC) structure. The IC structure includes an optical interposer having optical waveguides; a plurality of chip stacks disposed over the optical interposer, each of the plurality of chip stacks including a first photonic IC chip and a memory chip over the first photonic IC chip; and a plurality of first laser source chips disposed adjacent to the plurality of chip stacks, respectively, wherein the optical waveguides in the optical interposer are configured as an optical interconnect structure to couple with the memory chip through the first photonic IC chip.

### PRIORITY

This application claims the benefits of U.S. Prov. App. Ser. No. 63/626,345, filed Jan. 29, 2024. The entire disclosure of these applications is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs and, for these advances to be realized, similar developments in IC processing and manufacturing are needed. For example, memory macros require numerous input/output (I/O) ports because different memory macros have different I/O ports. The increasing I/O numbers may frustrate the scaling-up of memory capacity. Accordingly, although existing memory macro structures have been generally adequate for their intended purposes, they have not been entirely satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only except explicitly disclosed. In fact, the dimensions of the various features may be arbitrarily increased or reduced for clarity of discussion.

FIG. 1A illustrates a partial, simplified schematic diagram of a memory device structure or system according to embodiments of the present disclosure.

FIG. 1B illustrates a partial, simplified cross-sectional diagram of the memory device structure or system with an optical interposer according to embodiments of the present disclosure.

FIGS. 2A and 2C illustrate partial, simplified schematic diagrams of the memory device structure or system according to embodiments of the present disclosure.

FIG. 2B illustrates a partial, simplified cross-sectional diagram of the memory device structure or system according to embodiments of the present disclosure.

FIGS. 3A, 3B, 3C, 3D, 3E, 3F and 3G illustrates partial, simplified cross-sectional diagram of the memory device structure or system at various fabrication stages according to embodiments of the present disclosure.

FIG. 4 illustrates a flowchart of a method of making memory device structure or system according to embodiments of the present disclosure.

FIG. 5 illustrates a partial, simplified cross-sectional diagrams of the memory device structure or system according to embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

The present disclosure relates generally to opto-electronics systems and particularly to a semiconductor structure or an opto-electronics system having memory device and an optical interposer configured with efficient control and data communication and the methods thereof.

Optical data communication systems operate by modulating laser light to encode digital data patterns. The modulated laser light is transmitted through an optical data network from a sending node (e.g., an optical transmitter) to a receiving node (e.g., an optical receiver). The modulated laser light having arrived at the receiving node is de-modulated to obtain the original digital data patterns. Implementation and operation of optical data communication systems depend on having reliable and efficient mechanisms for transmitting laser light and detecting laser light at different nodes within the optical data network, and further depend on the structure of integrated electrical circuit, photonic circuit, and memory device.

The present disclosure provides an integrated circuit (IC) structure having memory device and optical link, and the method making the same. Especially, the sending and receiving nodes in an optical data network may be interconnected through an interposer, and the optical signal is transmitted through the interposer. Such interposer may be referred to as an optical interposer. Using optical interposers may reduce the length of the optical path and improve the optical signal integrity.

Furthermore, the memory device structure includes multiple memory macros each with a bank of memory cells configured in an array and formed in an IC chip (or die), which is referred to as a memory macro chip (or simply memory chip). Each memory chip is stacked on a photonic IC chip, which is further stacked on the optical interposer. A memory input/output (I/O) module is formed in a stand-alone chip (referred to as memory I/O chip) in a similar configuration. Particularly, the memory I/O chip is stacked on a photonic IC chip, which is further stacked on the optical interposer. In the disclosed embodiments, all memory macro chips belong to a same type, such as static random-access memory (SRAM), dynamic random-access memory (DRAM), floating-gate memory device or other proper type of memory device. Accordingly, all memory chips can share a single memory I/O chip with cost-effective efficiency.

The memory device structure may include other chip stacks formed on the optical interposer. For example, the memory device structure includes one or more electrical IC chip (EIC chip) in a chip stack configuration. Specifically, each EIC chip is stacked on a photonic IC chip, which is further stacked on the optical interposer.

In the disclosed memory device structure, all functional chips, such as the memory chips, the memory I/O chip and EIC chips have similar chip stacking configuration and are coupled together through the optical interposer, which provides a universal optical interface for integrating different memory with high coupling speed and enhanced efficiency. The signal is transferred through the optical interposer in optical mode, is converted to electrical signal through the corresponding PIC chip and is further coupled to the overlying chip (such as a memory chip, the memory I/O chip or an EIC chip) in electrical signal. The disclosed structure provides a memory macro-embedded silicon-photonics integration (COUPE) system on an optical interposer. The disclosed memory device structure enables scaling up memory capacity outside of I/O needs to consider different I/O, such as double data rate memory (DDR), and low power double data rate memory (LPDDR). The disclosed memory device structure also enables high performance computing (HPC) or large language model (LLM) in artificial intelligence (AI), which needs high capacity and bandwidth memory for within rack or data center. In some alternative embodiments, an optical signal in the optical interposer may be converted to electrical signal in the optical interposer and is thereafter electrically coupled with the chips overlying the optical interposer.

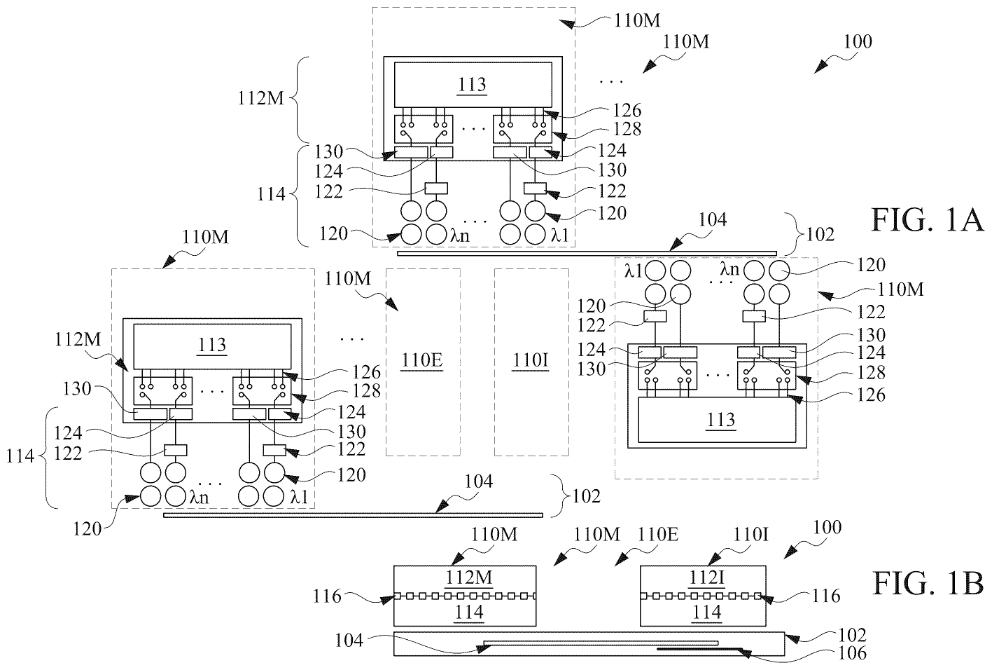

FIG. 1A is a partial, simplified schematic view of a memory device structure 100 and FIG. 1B is a partial, simplified cross-sectional view of the memory device structure (or IC structure) 100, constructed in accordance with some embodiments. Referring to FIGS. 1A and 1B, the memory device structure 100 includes an optical interposer 102 to provide communications among various IC modules, including receiving, transferring sending a signal in optical mode.

The optical interposer 102 includes integrated optical interconnect (structure) 104 that further includes various waveguides to transfer optical signals; and may further include optical micro-lens, optical couplers (such as grating couplers), other optical couplers or combinations thereof to receive and send optical signals. In some embodiments, the waveguides formed in the optical interposer 102 includes horizontal waveguides configured in parallel (or substantially in parallel) with each other and extending laterally, and vertical waveguides configured in parallel (or substantially in parallel) with each other and extending vertically so to form an interconnect structure to transfer an optical signal from one location to another location and further couple to the overlying chip stack. Especially, the waveguides are designed to transfer wideband optical signals, so that different optical signals with different wavelengths can be transferred simultaneously in parallel.

In some embodiments, the optical interposer 102 may additionally include electrical interconnect structure 106 to electrically couple the chip stacks to other structure, such as printed circuit board (PCB) bonded to the backside of the optical interposer 102, therefore providing some low frequency signals, such as power line Vdd and ground line Vss from the PCB.

The integrated optical interconnect 104 is similar to an electrical interconnect structure 106 but it is designed to carry and transfer optical signals instead of electrical signals while the electrical interconnect structure 106 carries and transfers electrical signals. The electrical interconnect structure 106 includes metal lines for horizontal routing and metal vias for vertical routing. Those metal lines and metal vias are embedded in one or more dielectric material for proper isolation. The integrated optical interconnect 104 includes waveguides made of optically transparent material, such as silicon oxide. Those waveguides are formed on a substrate and embedded in one or more proper material, such as a material with higher refractive index to achieve complete reflection and reduce the signal loss. The electrical interconnect structure 106 and the integrated optical interconnect 104 are interweaved in the optical interposer 102 but are independent from each other and designed to provide dual signal paths for electrical signals and optical signals.

The memory device structure 100 further includes various chip stacks 110 formed on the optical interposer 102. Each chip stack 110 includes two or more chips vertically stacked on the optical interposer 102. The chip stacks 110 include memory chip stacks 110M and a memory I/O chip stack 110I coupled with the integrated optical interconnect 104 of the optical interposer 102. The memory device structure 100 may further include one or more electrical IC chip stacks 110E coupled with the integrated optical interconnect 104. All those IC chip stacks 110M, 1101, 110E (collectively referred to as chip stacks 110) are coupled together through the integrated optical interconnect 104 of the optical interposer 102. Even though only two memory chip stacks 110M are shown in FIG. 1A for illustration, it is understood that the number of the memory chip stacks 110M may be any proper number, such as 3, 4, or 5. Similarly, it is understood that the number of the EIC chip stacks 110E may be any proper number, such as 2, 3, or 4, each be designed for its intended purposes, such as data processing, in-memory computing, imaging processing, other proper functional modules or a combination thereof.

Various IC chip stacks 110M, 1101, 110E are disposed on the optical interposer 102 and configured next to each other with proper spacing for optimized isolation and packing density. Each IC module includes a chip stack as illustrated in FIG. 1B. For example, each chip stack includes a photonic IC (PIC) chip 114 stacked on the optical interposer 102, and a functional IC chip 112 (such as a memory chip 112M, a memory I/O chip 112I, or an EIC chip 112E, collectively referred to with numeral 112) stacked on the PIC chip 114. As described above, a memory chip 112M includes a memory bank (or a memory macro) 113 having a plurality of memory cells configured in an array and formed in a single substrate, such as a silicon substrate. A memory I/O chip 112I includes an I/O circuit formed in a substrate and designed to perform input/output functions to those memory chips 112M. In some embodiments, the I/O circuit of the memory I/O chip 112I includes various I/O functional circuit blocks, such as a bit line decoder, a word line decoder, a bit line multiplexer, other suitable circuit block or a combination thereof. Note that the memory I/O chip 112I is not directly connected to the memory chips 112M but it is through the EIC chips 112E and the optical interposer 102, which will be further described later. An EIC chip 112E (not shown in FIG. 1B but will be described in other figures) includes an integrated circuit formed on a substrate and designed for data processing, in-memory computing function, imaging sensing module, other proper functional modules or a combination thereof.

In each chip stack, a functional IC chip 112 (such as a memory chip 112M, a memory I/O chip 112I, or an EIC chip 112E) is stacked on and is bonded to a photonic IC chip 114 with electrical communication therebetween. In some embodiments, the bonding between the functional IC chip 112 and the underlying PIC chip 114 includes a bonding interface 116 having a proper bonding structure, such as a hybrid bonding structure. In the hybrid bonding structure, the bonding interface 116 includes dielectric-to-dielectric bonding surfaces and metal-to-metal bonding surfaces. Especially, the metal-to-metal bonding surfaces provide conductive traces to provide electrical coupling between the PIC chip 114 and the corresponding functional IC chip 112.

As to the PIC chips 114, each PIC chip 114 includes opto-electronic structures, such as micro lens, grating couplers, optical modulators, photo detectors (such as photodiode or PD), and other components, a transimpedance amplifier (TIA), or a combination thereof, to receive optical signals from the underlying optical interposer 102; converts the optical signals to electrical signals and send the electrical signals to the overlying functional chip 112; receive electrical signals from the overlying functional chip 112; and converts the electrical signals to optical signals and send the optical signals to the underlying optical interposer 102. Especially, the PIC chips 114 includes multiple micro ring resonators (also referred to as optical ring resonators or ORS) 120 with different ring dimensions (such as radius) so that with different resonating wavelength λ (or frequency) to select light signal in particular wavelength λ, such as λ1, λ2, . . . , λi, . . . λn. Those micro-ring resonators 120 are configured to be associated with respective bit lines (or word lines). In some embodiments, each type of micro-ring resonators 120 with a certain dimension may include two or more identical micro ring resonators configured in series to enhance the signal selection and signal strength. Thus, some of the PIC chips 114 includes an array of micro ring resonators 120 with different characteristics, such as different dimensions, different materials, configured in an array, and functioning as an address decoder. Different micro ring resonators 120 in each PIC chip 114 can be formed with different characteristics (e.g., different sizes and/or materials) to operate with different lights of various wavelengths. Because different lights of different wavelengths can be transferred/processed simultaneously without interference, the memory bandwidth can be further improved.

The communications among various functional IC chips 112 are further described. An electrical signal from a functional IC chip 112 is sent to the underlying PIC chip 114; the electrical signal is converted to an optical signal by the corresponding PIC chip 114; the optical signal is transmitted through the waveguides of the optical interposer 102 to another PIC chip 114; the optical signal is converted back to an electrical signal; and the electrical signal is sent to the overlying functional IC chip 112. Taking a communication between a memory chip 112M and the memory I/O chip 112I as an example for illustration. When an electrical signal is generated by the memory I/O chip 112I and is addressed to a particular bit line (such as bit line i), this electrical signal is converted to an optical signal carried in light with a certain wavelength λi, which matches to the resonating wavelength λi of the micro ring resonators 120 associated with that bit line. Then the optical signal is sent to the memory chip stack 110M through the waveguides of the optical interposer 102. The PIC chip 114 of the memory chip stack 110M uses the array of micro ring resonators 120 to select the optical signal send the intended path associated with the micro ring resonator 120 with the resonating wavelength λi. The PIC chip 114 further converts the optical signal to an electrical signal by a suitable optical-to-electrical (OE) converter 122, such as a photodiode, other suitable OE converter, or a combination thereof. The electrical signal may be further processed, such as amplified using a suitable amplifier 124, such as a transimpedance amplifier (TIA). The electrical signal is further sent to a targeted bit line (or word line) 126, such as being through a multiplexer 128. The power signal, such as a high power Vdd and a low power Vss, may be provided to the memory cells of the memory macro 113 through a proper circuit, such as a driver 130. The communications between various functional IC chips 112 and PIC chips 114 may include any proper coupling and communication structure and technologies (such as Serdes) to achieve high speed effect. Serdes technology is utilized to transmit high-speed data between memory, processors, and network interfaces, which is designed for datacenters, telecommunications, and high-performance computing.

In an embodiment, the multiplexer in memory chip can match the operation speed between the optical modulator and memory macros. For example, the data from the multiplexer of the memory macro has lower data rate while the optical modulator has a higher data rate. The multiplexer or with additional circuit can be designed to transfer more data in parallel and send those data simultaneously to the optical modulator with matching speed.

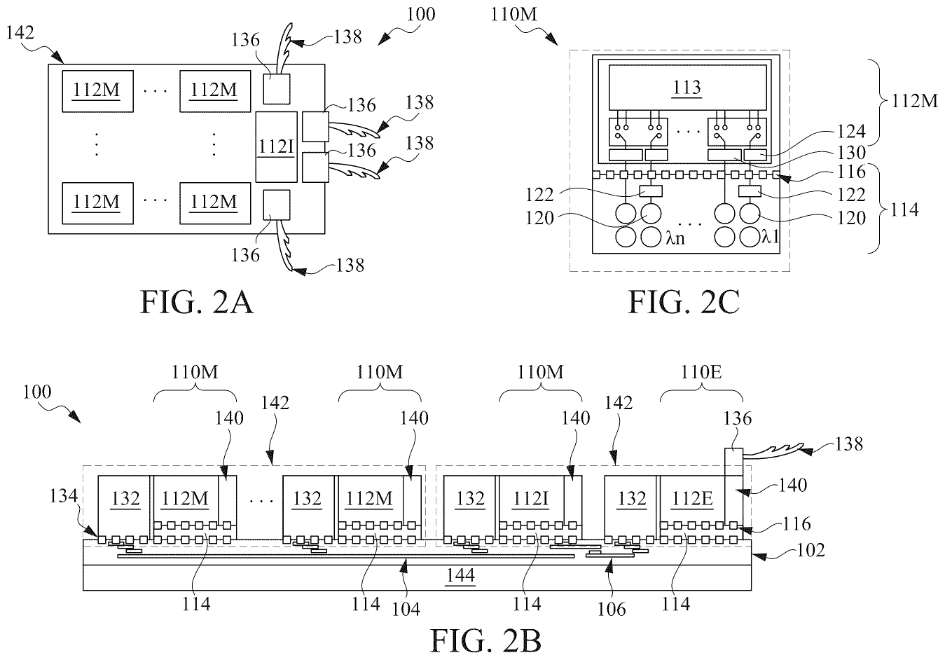

The memory device structure 100 is further described in detail with reference to FIGS. 2A through 2C. FIG. 2A is a partial, simplified schematic view of a memory device structure 100, FIG. 2B is a partial, simplified cross-sectional view of the memory device structure 100, and FIG. 2C is a partial, simplified schematic view of a memory device structure 100, constructed in accordance with some embodiments. Particularly, FIG. 2C only includes one memory chip stack module 110M. The memory device structure 100 in FIGS. 2A-2C is similar to the memory device structure 100 in FIGS. 1A and 2B. the similar descriptions are not repeated here for simplicity.

Referring to FIGS. 2A through 2C, the memory device structure 100 includes an optical interposer 102 to provide communications among various IC modules, including receiving, transferring sending a signal in optical mode. The memory device structure 100 further includes various chips stacks 110, such as memory chip stacks 110M, a memory I/O chip stack 110I and EIC chip stack 110E disposed on, bonded to, and optically coupled with the optical interposer 102, as described above. The memory device structure 100 further includes laser source chips 132 disposed on adjacent to the PIC chips 114. A laser source chip 132 is designed as a laser source to generate laser light with wideband and coupled with the adjacent PIC chip 114 to provide light thereto. In some embodiments, the laser source chips 132 include one or more optical generating devices (such as light-emitting diodes or LEDs) to generate laser light with different wavelengths. For example, when an electrical signal is sent to the PIC chip 114, the PIC chip 114 receives the light from the adjacent laser source chip 132 and modulates the light to carry the signal from the electrical signal, thereby forming an optical signal. The optical signal is thereafter sent to the optical interposer 102 and further transferred to other chip stacks 110 such as a memory chip stack 110M. In some embodiments, the laser source chip 132 is coupled with the adjacent PIC chip 114 through the optical interposer 102. Therefore, the interface 134 between the laser source chip 132 and the optical interposer 102 provides a mechanism of optical coupling (optical communication). For example, the interface 134 includes portions made of a transparent material (such as silicon oxide) to transfer light to or from the waveguides of the optical interposer 102. The same interface 134 is formed between the PIC chip 114 and the optical interposer 102 as illustrated in FIG. 2C. In some embodiments, the laser source chip 132 and the PIC chip 114 are laterally contacted to form an interface with direct light coupling.

The memory device structure 100 includes one or more fiber array unit (FAU) 136 functioning as input/output ports 138 of the memory device structure 100. The FAU 136 includes a plurality of optical fibers configured in array and connected to input/output signals in light mode. The FAU 136 is attached to one or more chip stacks 110, such as being attached to an EIC chip stack 110E (as illustrated in FIG. 2B), being attached to a memory I/O chip stack 110I (as illustrated in FIG. 2AB), being attached to other chip stacks, or a combination thereof. In some embodiments illustrated in FIG. 2A, four fiber array units 136 are attached to the memory I/O chip stack 1121. In some embodiments illustrated in FIG. 2B, one or more fiber array unit 136 is attached to the EIC chip 112E.

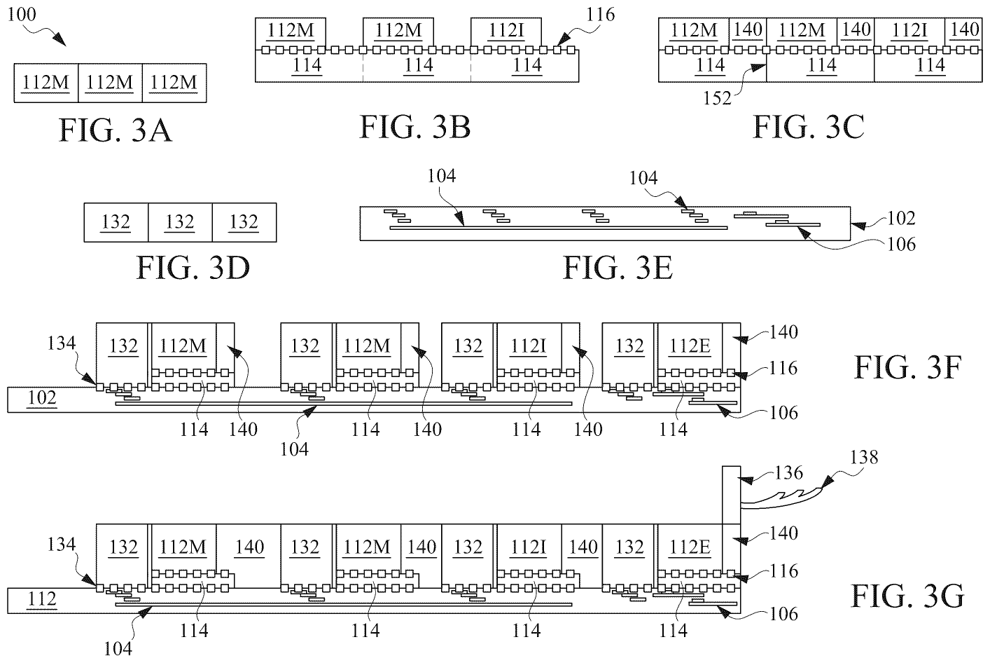

The memory device structure 100 includes dielectric features 140 of one or more dielectric material, such as silicon oxide. In some embodiments, the dielectric features 140 fill in the gaps among the chip stacks 110, such as those shown FIG. 3G. In some embodiments, the FAU 136 is disposed on the dielectric feature 140 so that the dielectric feature 140 serves as an optical path to the optical signals from and to the FAU 136. In furtherance of the embodiments, the dielectric feature 140 includes a top portion curved to function as a micro lens to the optical signal. An optical device, such as grating coupler or reflective mirror is formed underlying the dielectric feature, such as on a portion of the PIC chip 114 underlying the dielectric feature 140.

The memory device structure 100 is further sealed in an IC packaging 142 such as 3DIC packaging. In some embodiments, the memory device structure 100 is sealed in a single packaging to enclose various chip stacks 110. In some embodiments, various chip stacks 110 are sealed in two or more packaging structures with considerations of design requirements, stress and sealing effect and/or other relevant factors. In various embodiments, the sealing packaging structure 142 includes various sealing components, such as metal lid, metal frame, metal housing, underfilling material, glue, thermal interfacial material, heat spreader, other sealing features, or a combination thereof, configured to form one or more proper sealing structure, such as hermetic sealing structure.

The memory device structure 100 is further attached to on a printed circuit board (PCB) 144, another 3DIC structure, a substrate, an interposer, other suitable structure of a combination thereof. The memory device structure 100 is bonded to and electrically coupled with the PCB 144. For example, the bonding surface therebetween includes a controlled collapse chip connection (C4) structure, micro bumps, hybrid bonding structure, other suitable bonding features or a combination thereof.

As described above, the optical interposer 102 may additionally include an electrical interconnect structure 106 to provide a mechanism to electrically connect the PCB 144 to the chip stacks 110. In furtherance of the embodiment, high frequency signals are coupled to the memory device structure through the FAU 136 in optical mode for high speed while low frequency signals, such as power lines Vss and Vdd, are coupled to the memory device structure through the PCB 144 in electrical mode without impacting the overall system performance.

The memory device structure 100 may have other proper structure and may include additional features, such as additional chip stacks or chips. The memory device structure 100 is formed by a proper method, such as a method described below with reference to FIGS. 3A through 3G.

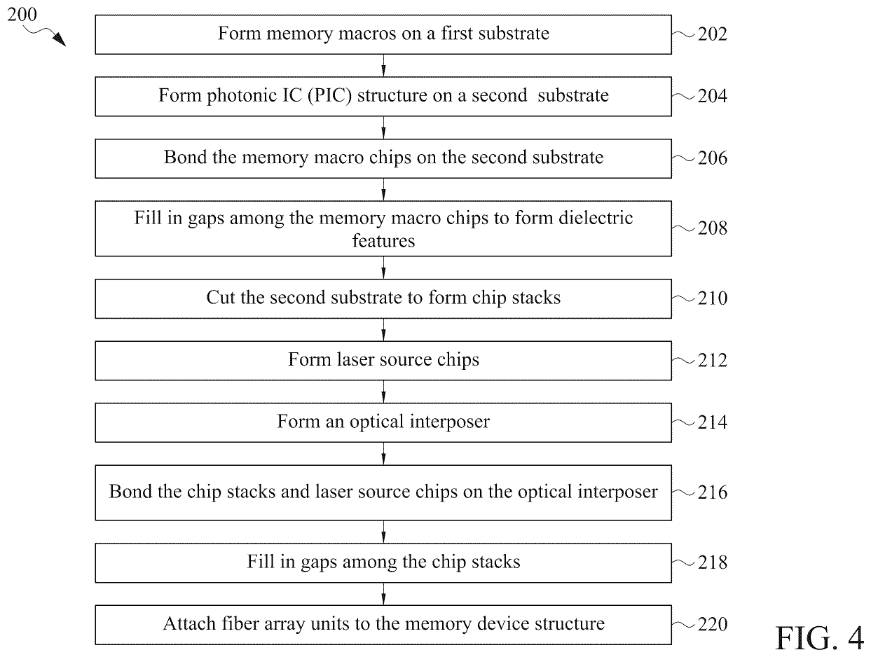

FIGS. 3A through 3G are partial, simplified, and sectional views of a memory device structure 100 at various fabrication stages, constructed in accordance with some embodiments. FIG. 4 is a flowchart of a method 200 making the memory device structure 100, constructed in accordance with some embodiments. The memory device structure 100 and the method 200 making the same are further described in detail with reference to FIGS. 3A through 3G and 4 according to some embodiments.

Referring to FIGS. 3A and 4, at operation 202, various memory macros 112M are formed on a first substrate, such as a silicon substrate or other suitable substrate. The memory macros 112M include same type of memory structure, such as SRAM, DRAM, NAND, nonvolatile memory devices, magnetic memory devices, resistive memory devices, or other type memory devices, so that all memory macros 112M are able to be controlled by the same memory I/O chip 112I through the integrated optical interconnect 104 of the optical interposer 102. Each memory macro 112M includes a plurality of memory cells configured in an array and may additionally include other circuit features, such as driving circuit, amplifiers, multiplexer, or a combination thereof. The operation 202 includes forming the memory macros 112M with various fabrication steps that includes various frontend of line (FEOL) processing steps and backend of line (BEOL) processing steps, such as depositions, etching, lithography process, and ion implantations. The operation 202 further includes a chemical mechanical polishing (CMP) process to planarizing the top surface and cutting (sawing) into separate memory chips (also referred to by 112M).

Referring to FIGS. 3B and 4, at operation 204, various PIC structures 114 are formed on a second substrate. The PIC structure 114 includes the second substrate, such as a silicon substrate, various dielectric layers and multiple optical structures in the dielectric layers. For example, the multiple optical structures may include grating coupler(s), modulator(s), photo detector(s), and waveguide(s) discussed above. The operation 204 includes FEOL and BEOL processing steps. Each PIC structure 114 is a single PIC chip after cutting at later stages.

Still referring to FIGS. 3B and 4, at operation 206, the memory macro chips 114M are bonded to the second substrate over the PIC structures 114. The bonding structure and bonding method may include any suitable bonding structure and method. In the disclosed embodiment, the bonding method includes chip-on-wafer (CoW) bonding method. For example, each memory chip 112M is picked and placed on a PIC structure 114 on the second substrate and bonded thereto. In some embodiments, the bonding structure includes a hybrid bonding structure that dielectric to dielectric bonding interfaces and metal to metal bonding interfaces, which provide conductive routing for electrical coupling between the memory chips 112M and the PIC chips 114. In some embodiments, other functional IC structures 112, such as memory I/O chip 112I and EIC structure 112E are formed on the same substrate or separately formed on other substrate, disposed over the PIC structures 114 and are bonded to the second substrate.

Referring to FIGS. 3C and 4, at operation 208, one or more dielectric material is filled in the gaps among the memory chips 112M, thereby forming dielectric filling features (or dielectric features) 140. In some embodiments, the dielectric features 140 include silicon oxide, which is transparent and can be used as optical paths, as described above. The operation 208 includes deposition and thereafter CMP and may further include other processing steps. Deposition may include chemical vapor deposition (CVD), flowable CVD (FCVD), other suitable deposition technique or a combination thereof.

Still referring to FIGS. 3C and 4, at operation 210, the second substrate is cut, along scribing lines 152, into a plurality of chip stacks 110 each having a PIC chip 114 and a memory macro chip 114M stacked and bonded together. Other functional IC chips 112I and 112E are also bonded over PIC structures 114 and are cut into respective chip stacks, such as 1101 and 110E.

Referring to FIGS. 3D and 4, at operation 212, various laser source chips 132. The operation 212 includes forming laser source structures (also referred to by the numeral 132) on a third substrate, such as a silicon substrate or other suitable substrate. The operation 212 includes FEOL and BEOL processing steps to form laser source structures 132. The operation 212 further includes cutting the laser source structures 132 into laser source chips 132.

Referring to FIGS. 3E and 4, at operation 214, an optical interposer 102 is formed on a fourth substrate. As described above, the optical interposer 102 includes integrated optical interconnect 104 having waveguides and may include other optical features, such as grating couplers, reflective mirrors, micro lens, amplifiers, or a combination thereof. The optical interposer 102 includes silicon, silicon oxide, silicon nitride, other proper dielectric material or a combination thereof to form waveguides and other optical components. The operation 214 includes deposition, lithography process, etching, CMP or combinations thereof. In some examples, the waveguides include a dielectric material feature surrounded by another dielectric material of lower refractive index, such as amorphous silicon or silicon nitride surrounded by silicon oxide; or silicon nitride surrounded by silicon. In the last case, the waveguides can be formed as silicon nitride features in a silicon substrate. The waveguides include horizontal waveguides and vertical waveguides to form an optical interconnect structure. In some embodiments, the optical interposer 102 also includes an electrical interconnect structure 106 that having various metal lines and vias to provide additional electrical communication, such as communications between PCB and chip stacks 110. The formation of the electrical interconnect structure 106 includes any suitable method, such as damascene process, deposition and patterning (that further includes lithography process and etch), or a combination thereof. The optical interposer 102 and the operation 214 are further described in detail later.

Referring to FIGS. 3F and 4, at operation 216, the chip stacks 110 and the laser source chips 132 are bonded to the optical interposer 102. The bonding structure and bonding method may include any suitable bonding structure and method. In the disclosed embodiment, the bonding method includes chip-on-wafer (CoW) bonding method. For example, the chip stacks 110 and the laser source chips 132 are picked and placed on the optical interposer 102. In some embodiments, the bonding structure includes a hybrid bonding structure that dielectric-to-dielectric bonding interfaces and metal to metal bonding interfaces. The dielectric-to-dielectric bonding interfaces or portions thereof provide optical paths and metal to metal bonding interfaces provide conductive routing for electrical coupling between the optical interposer 102 and the PIC chips 114. Additionally, other chip stacks 110, such as 1101 and 110E, are also bonded to the optical interposer 102 in a similar method.

Referring to FIGS. 3G and 4, at operation 218, one or more dielectric material is filled in the gaps among the chip stacks 110 and the laser source chips 132, thereby forming dielectric filling features (or dielectric features), being referred to by the same numeral 140. In some embodiments, the dielectric features 140 include silicon oxide, which is transparent and can be used as optical paths, as described above. The operation 208 includes deposition and thereafter CMP and may further include other processing steps. Deposition may include CVD, FCVD, other suitable deposition technique or a combination thereof.

Still referring to FIGS. 3G and 4, at operation 220, the fiber array units 136 are to the memory device structure 100, such as attached to the dielectric features 140 so that the dielectric features 140 can function as optical paths to the fiber array units 136. The fiber array units 136 are connected to fibers 138 serving as input/output ports to the memory device structure 100 in light mode. The fiber array units 136 are bonded to the memory device structure 100 with proper technique, such as glue or other bonding method. The operation 220 may also include other processing steps, such as sealing the memory device structure 100 to form a sealing packaging structure 142, such as shown in FIG. 2B.

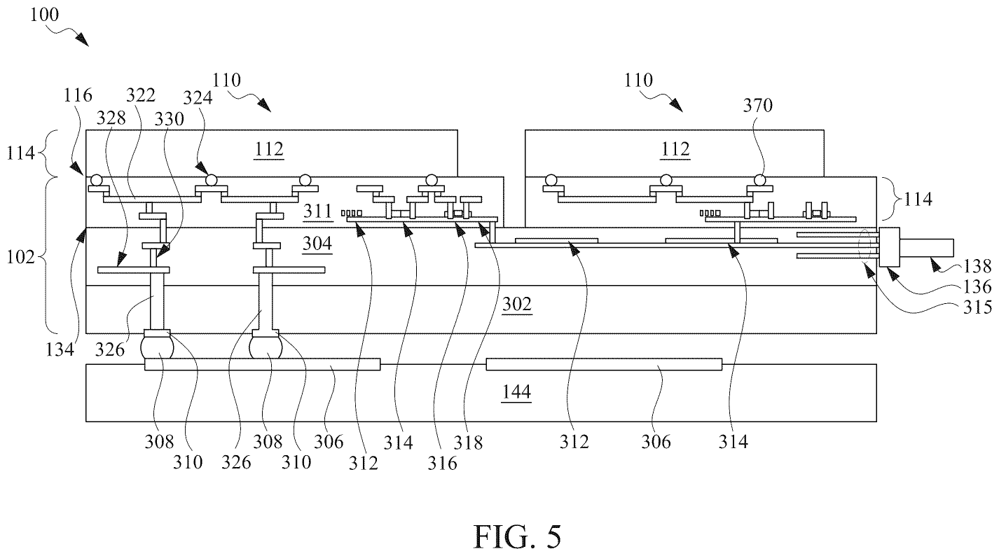

FIG. 5 is a sectional view, in partial and simplified, of the memory device structure 100 according to some embodiments. Particularly, FIG. 5 illustrates optical interposer 102, the chip stacks 110 and various bonding interfaces with more details, which are further described in detail.

In FIG. 5, the memory device structure 100 includes an optical interposer 102 formed on a substrate 302. In an embodiment, the substrate 302 is a semiconductor substrate, such as a silicon substrate (e.g., a silicon wafer or a part thereof). Additionally, or alternatively, the substrate 302 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used as the substrate 302. In some embodiments, the substrate 302 may include a glass substrate or a ceramic substrate.

In the illustrated embodiment, the optical interposer 102 includes a dielectric layer 304 formed on the substrate 302. In an embodiment, the dielectric layer 304 includes silicon dioxide, and various optical structures 312, 314, and 316 are formed in the dielectric layer 304 and include silicon nitride-based optical structures. In other words, the optical structures 312, 314, and 316 may utilize the differences between the refractive indexes of silicon nitride and silicon dioxide to confine and transmit light. For example, the optical structures 312, 314 and 316 may include a dielectric material with a higher refractive index to achieve complete reflection. The dielectric layer 304 may include other suitable dielectric materials to achieve the same confinement effect in alternative embodiments. In various embodiments, the optical interposer 102 may include silicon-based photonic devices embedded in the dielectric layer 304 of silicon oxide or silicon nitride-based photonic devices embedded in the dielectric layer 304 of silicon oxide.

In an embodiment, the optical structures 312 and 314 include waveguides for transmitting and receiving optical signals to and from the optical structures in the dielectric layer 304. In some embodiments, the optical structures 312 and 314 are disposed at different vertical levels in the dielectric layer 304. In an embodiment, the optical structure 316 may include an edge coupler for coupling the optical structure 314 (e.g., a waveguide) with a fiber array unit 136 that may be disposed on a side or alternatively on top of the optical interposer 102. In an embodiment, the edge coupler 315 includes multiple layers of optical paths that provide high tolerance for alignment with the fiber array unit 136. The fiber array unit 136 may be further coupled with an optical fiber 138 for connecting with another structure or system (not shown) for input/output signals.

The formation of the optical interposer 102 may include any suitable method, such as deposition, etching and lithography process to form those optical structures at different levels layer by layer. In some embodiments, the method may include various layers are separately formed and then bonded together, which increases the flexibility of integrating different types of photonic devices into the optical interposer.

The optical interposer 102 and the overlying bonded chip stacks 110 may be further bonded to another substrate 144. In some embodiments, the substrate 144 is a printed circuit board (PCB), such as FR4 PCB. FR4 is a class of PCB base material made from a flame-retardant epoxy resin and glass fabric composite. In some embodiments, the substrate 144 may include an organic dielectric material, such as a polymer, which may include polyimide, polybenzoxazole (PBO), benzocyclobutene (BCB), other suitable polymer-based material, or combinations thereof. The substrate 144 further includes metallization patterns 306 (such as metal traces, metal pads, and metal vias) on or in the organic material(s). The metallization patterns 306 may include a metal or a metal alloy, such as copper, titanium, tungsten, aluminum, the like, or combinations thereof, and may be formed using deposition and patterning processes.

The substrate 302 and the substrate 144 are electrically and mechanically coupled or connected by way of conductive connectors 308. The conductive connectors 308 may be ball grid array (BGA) connectors, solder balls, metal pillars, C4 bumps, micro bumps, electroless nickel-electroless palladium-immersion gold technique (ENEPIG) formed bumps, or the like. The conductive connectors 308 may be formed of a metal or metal alloy, such as solder, copper, aluminum, gold, nickel, silver, palladium, tin, the like, or a combination thereof. In some embodiments, the conductive connectors 308 are formed using methods such as evaporation, sputtering, electroplating, electroless plating, printing, solder transfer, ball placement, reflow, or the like. The conductive connectors 308 are connected to conductive pads (or under bump metallurgies) 310 on the bottom surface of the substrate 302 and are connected to the metallization patterns 306 on the top surface of the substrate 144.

Various chip stacks 110 are bonded to the optical interposer 102. Each chip stack 110 includes a PIC chip 114 and a functional IC chip 112, such as a memory chip 112M, a memory I/O chip 112I, an EIC chip 112E or a combination thereof. In some embodiments, the functional IC chip 112 of the memory device structure 100 includes multiple memory chips 112M, a single memory I/O chip 112I, and one or more EIC chip 112E.

A PIC chip 114 includes a substrate, various optical structures and electrical structure formed thereon. The optical structures include optical processing structures to receive, transmit, modulate optical signals; and optic-electric structures to convert optical signals to electrical signals or vice versa. Those structures are also collectively referred to as optical structures. The electrical structures include various structures to process electrical signals, such as various devices (including transistors, capacitors, diodes and so on) and interconnect structure to couple those devices. In FIG. 5, optical structures 312, 314, 316, 318 are shown for illustration, according to some embodiments.

In an embodiment, the optical structures or a subset thereof, are formed in one or more dielectric layer 311 includes silicon dioxide. The dielectric layer 311 may include other dielectric materials in alternative embodiments. In an embodiment, the optical structure 312 may include a grating coupler 312. In an embodiment, the grating coupler 312 includes several segments with a periodic configuration to achieve grating mechanism. The grating coupler 312 may be coupled with a laser generator, such as from the laser source chip 132 (such as shown in FIG. 3) and be configured to transform a laser signal into a modulated light signal, or vice versa. In some embodiments, the grating coupler 312 may include a metal or a dielectric material with a dielectric constant higher than that of silicon dioxide or that of the dielectric layer 311.

In an embodiment, the optical structure 314 may include a photonic modulator and be referred to as a modulator 314. In some embodiments, the modulator 314 may include silicon, germanium, tin, a group III element, such as aluminum, indium, or gallium, and/or a group V element, such as arsenic, phosphorous, antimony. In an embodiment, the modulator 314 may be configured to transform a laser signal into a modulated light signal comprising or carrying a high-speed data signal. The modulator 314 may be electrically coupled to and/or controlled by a die 402, further discussed below.

In an embodiment, the optical structure 316 may include a photo detector and be referred to as a photo detector 316. In an embodiment, the photo detector 316 may include a photo diode (or photodiode), a photo transistor, or other types of photo detectors. The photo detector 316 is configured to transform a light signal into an electrical signal. In some embodiments, the photo detector 316 may include silicon, germanium, tin, a group III element, such as aluminum, indium, or gallium, and/or a group V element, such as arsenic, phosphorous, antimony.

In an embodiment, the optical structure 318 may include a waveguide and be referred to as a waveguide 318. In an embodiment, the waveguide 318 includes a silicon waveguide, which uses the differences between the refractive indexes of silicon and the dielectric layer 311 (e.g., silicon dioxide) to confine and transmit light. In alternative embodiments, the waveguide 318 may include a dielectric waveguide or a plasmonic waveguide. A dielectric waveguide may include a patterned silicon nitride, amorphous silicon, or a high dielectric material surrounded by a low dielectric constant material of the dielectric layer 311, such as silicon dioxide. A plasmonic waveguide may include patterned metal nano wires surrounded by a dielectric material of the dielectric layer 311.

The PIC chips 114 are bonded to the optical interposer 102 with a bonding interface 134 to be optically coupled with each other and in communication through optical signals. The optical structures in the optical interposer 102 and the optical structures in the PIC chips 114 are designed and configured with such communications. For examples, the waveguides in the optical interposer 102 and the PIC chips 114 have vertical waveguides aligned and in direct contact with each other.

The PIC chips 114 also includes electrical interconnect structure 322 that further includes metal lines and vias. The functional IC chips 112 are bonded to the PIC chips 114 with bonding interface 116 to have electrical communications therebetween, such as through conductive connectors 324. In some embodiments, the bonding interface 116 between the functional IC chip 112 and the underlying PIC chip 114 includes a proper bonding structure, such as a hybrid bonding structure. In the hybrid bonding structure, the bonding interface 116 includes dielectric-to-dielectric bonding surfaces and metal-to-metal bonding surfaces. Especially, the metal-to-metal bonding surfaces provide conductive traces to provide electrical coupling between the PIC chip 114 and the corresponding functional IC chip 112.

In some embodiments, the optical interposer 102 also includes an electrical interconnect structure 106 to provide electrical communication between the PCB 144 and the PIC chips 114. In an embodiment, the optical interposer 102 includes through substrate via (TSV) features 326, metal lines 328 and vias 330 to form the electrical interconnect structure 106 to provide electrical connections between the PIC chips 114 (and the functional IC chips 112) and the PCB 144 through the bonding interface between the PCB 144 and the optical interposer 102, and through the bonding interface 134 between the PIC chips 114 and the optical interposer 102.

Other features and processes may also be included in the embodiments discussed above. For example, the memory device structure may include other optical structures and electrical structures, such as back reflective mirrors, optical amplifier, digital devices (such as bipolar transistors), passive devices (such as capacitors and inductors), other suitable devices or combinations thereof. In another example, testing structures may be included to aid in the verification testing of the memory device structure 100. Additionally, the structures and methods disclosed herein may be used in conjunction with testing methodologies that incorporate intermediate verification of known good dies (or known good device layers) to increase the yield and decrease costs.

The present disclosure provides an integrated circuit (IC) structure having memory device and optical link, and the method making the same. Especially, the sending and receiving nodes in an optical data network may be interconnected through an interposer, and the optical signal is transmitted through the interposer. Furthermore, the memory device structure includes multiple memory macros each with a bank of memory cells configured in an array and formed in an IC chip. Each memory chip is stacked on a photonic IC chip, which is further stacked on the optical interposer, forming chip stacks over the optical interposer in 3DIC packaging structure. A plurality of memory chip stacks, a memory I/O chip stack, and one or more EIC chip stack are all coupled to the optical interposer and communicate in optical mode with each other through the optical interposer. All functional chips, such as the memory chips, the memory I/O chip and EIC chips have similar chip stacking configuration and are coupled together through the optical interposer, which provides a universal optical interface for integrating different memory with high coupling speed and enhanced efficiency. A signal is transferred through the optical interposer in optical mode, is converted to electrical signal through the corresponding PIC chip and is further coupled to the overlying chip (such as a memory chip, the memory I/O chip or an EIC chip) in electrical signal.

The disclosed structure provides a memory macro-embedded COUPE system on an optical interposer. The disclosed memory device structure enables scaling up memory capacity outside of I/O needs to consider different I/O, such as double data rate memory (DDR), and low power double data rate memory (LPDDR). The disclosed memory device structure also enables high performance computing (HPC) or large language model (LLM) in artificial intelligence (AI), which needs high capacity and bandwidth memory for within rack or data center.

Although not intended to be limiting, one or more embodiments of the present disclosure provide many benefits to semiconductor devices and manufacturing, such as three-dimensional integrated circuits or systems having optical devices. For example, multiple memory macros are directly optically linked to the memory I/O module, memory capacity is greatly increased. A plurality of memory chips is able to share a single memory I/O chip. Data of these memory chips can be transferred to the memory I/O chip by optical communication achieved by the PIC chip and waveguides in the optical interposer. Multiplexer in memory chip can match the operation speed between optical modulator and memory macros. Different micro ring resonators in each PIC chip can be formed with different characteristics (e.g., different sizes and/or materials) to operate with different lights of various wavelengths. Because different lights of different wavelengths can be transferred/processed simultaneously without interference, the memory bandwidth can be further improved.

The disclosed structure is also applicable for compute-in-memory (CIM) or near-memory-compute (NMC). In another example, embodiments of the present disclosure provide an optical interposer that can be used in three-dimensional integrated circuits or systems. The optical interposer provides opto-electronic devices along with waveguides. In various embodiments, interfaces between the optical interposer and PIC chips are optically coupled, which enables high speed and efficient communications among the memory macros, memory I/O chip and EIC chips. Various bonding interfaces and bonding structures may use existing or future-developed bonding methods. The disclosed structures and methods can be easily integrated into existing semiconductor (such as CMOS) manufacturing processes.

In one example aspect, the present disclosure provides an integrated circuit (IC) structure. The IC structure includes an optical interposer having optical waveguides; a plurality of chip stacks disposed over the optical interposer, each of the plurality of chip stacks including a first photonic IC chip and a memory chip over the first photonic IC chip; and a plurality of first laser source chips disposed adjacent to the plurality of chip stacks, respectively, wherein the optical waveguides in the optical interposer are configured as an optical interconnect structure to couple with the memory chip through the first photonic IC chip.

In another example aspect, the present disclosure provides an integrated circuit (IC) structure. The IC structure includes an optical interposer having optical waveguides; a plurality of memory chip stacks disposed over the optical interposer, each of the plurality of memory chip stacks including a first photonic IC chip and a memory chip disposed over and bonded to the first photonic IC chip; a plurality of first laser source chips disposed adjacent to the plurality of memory chip stacks, respectively; a memory input/output (I/O) chip stack disposed over the optical interposer, wherein the memory I/O chip stack includes a second photonic IC chip and a memory I/O chip disposed over and bonded to the second photonic IC chip; and a second laser source chip disposed adjacent to the memory I/O chip stack, wherein the optical waveguides in the optical interposer are configured to couple the memory chip with the memory I/O chip through the first and second photonic IC chips.

In another example aspect, the present disclosure provides a method. The method includes forming photonic integrated circuit (IC) structures on a first substrate; bonding memory chips to the photonic IC structures formed on the first substrate; sawing the first substrate, resulting in memory chip stacks each including one of the photonic IC structures and one of the memory chips; forming an optical interposer; and bonding the memory chip stacks and laser source chips on the optical interposer in a configuration such that one of the laser source chips is adjacent to one of the memory chip stacks.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) structure, comprising:
an optical interposer having optical waveguides;
a plurality of chip stacks disposed over the optical interposer, each of the plurality of chip stacks including a first photonic IC chip and a memory chip over the first photonic IC chip; and
a plurality of first laser source chips disposed adjacent to the plurality of chip stacks, respectively, wherein the optical waveguides in the optical interposer are configured as an optical interconnect structure to couple with the memory chip through the first photonic IC chip.

2. The IC structure of claim 1, wherein the optical interposer further includes conductive features configured as an electrical interconnect structure to electrically couple with the memory chip.

3. The IC structure of claim 2, wherein
the optical interposer includes a substrate;
the optical waveguides formed on the substrate and are made of silicon or silicon nitride; and
the conductive features formed on the substrate and are made of a metal, a metal alloy or a combination thereof, wherein the optical waveguides and the conductive features are interweaved and independently couple to the memory chip.

4. The IC structure of claim 3, wherein the optical waveguides include lateral waveguides and horizontal waveguides configured to guide light to the first photonic IC chip.

5. The IC structure of claim 1, further comprising a memory input/output (I/O) chip stack disposed over the optical interposer, wherein the memory I/O chip stack includes
a second photonic IC chip;
a memory I/O chip over the second photonic IC chip; and
a second laser source chip disposed adjacent to the memory I/O chip, wherein the optical waveguides in the optical interposer are configured to optically couple the memory I/O chip through the second photonic IC chip.

6. The IC structure of claim 5, further comprising an electrical chip stack disposed over the optical interposer, wherein the electrical chip stack includes
a third photonic IC chip;
an electrical IC chip over the third photonic IC chip; and
a third laser source chip disposed adjacent to the electrical IC chip, wherein the optical waveguides in the optical interposer are configured to optically couple the electrical IC chip through the third photonic IC chip.

7. The IC structure of claim 5, further comprising a fiber array unit attached to the memory I/O chip and configured to provide input and output signals in light mode.

8. The IC structure of claim 1, wherein each of the first laser source chips is configured to provide light to the first photonic chip in the corresponding one of the chip stacks.

9. The IC structure of claim 1, wherein the optical interposer, the chip stacks and the first laser source chips are sealed in a same packaging.

10. The IC structure of claim 1, wherein each of the first photonic IC chips includes a multiple of micro ring resonators with different dimensions designed to have different resonating wavelength.

11. The IC structure of claim 1, wherein the first photonic IC chip and chip in each corresponding one of the chip stacks are bonded together through hybrid bonding and are electrically coupled through bond metal features in a bonding interface.

12. An integrated circuit (IC) structure, comprising:
an optical interposer having optical waveguides;
a plurality of memory chip stacks disposed over the optical interposer, each of the plurality of memory chip stacks including a first photonic IC chip and a memory chip disposed over and bonded to the first photonic IC chip;
a plurality of first laser source chips disposed adjacent to the plurality of memory chip stacks, respectively;
a memory input/output (I/O) chip stack disposed over the optical interposer, wherein the memory I/O chip stack includes a second photonic IC chip and a memory I/O chip disposed over and bonded to the second photonic IC chip; and
a second laser source chip disposed adjacent to the memory I/O chip stack, wherein the optical waveguides in the optical interposer are configured to couple the memory chip with the memory I/O chip through the first and second photonic IC chips.

13. The IC structure of claim 12, wherein
the optical waveguides in the optical interposer are configured as an optical interconnect structure to optically couple the waveguides with the first photonic IC chip; and
the first photonic IC chip is electrically coupled to the memory chip.

14. The IC structure of claim 12, wherein the optical interposer further includes conductive features configured as an electrical interconnect structure to electrically couple with the memory chip and the first photonic IC chip to provide power thereto.

15. The IC structure of claim 12, further comprising a fiber array unit attached to the memory I/O chip and configured to provide input and output signals in light mode.

16. The IC structure of claim 12, wherein each of the first laser source chips is configured to provide light to the first photonic chip in the corresponding one of the chip stacks.

17. The IC structure of claim 12, wherein each of the first photonic IC chips includes a multiple of micro ring resonators with different dimensions designed to have different resonating wavelength.

18. The IC structure of claim 12, wherein
the first photonic IC chip and chip in each corresponding one of the chip stacks are bonded together through hybrid bonding and are electrically coupled through bond metal features in a bonding interface; and
the optical interposer, the chip stacks and the first laser source chips are sealed in a same packaging.

19. A method, comprising:
forming photonic integrated circuit (IC) structures on a first substrate;
bonding memory chips to the photonic IC structures formed on the first substrate;
sawing the first substrate, resulting in memory chip stacks each including one of the photonic IC structures and one of the memory chips;
forming an optical interposer; and
bonding the memory chip stacks and laser source chips on the optical interposer in a configuration such that one of the laser source chips is adjacent to one of the memory chip stacks.

20. The method of claim 19, further comprising:
bonding a memory input/output (I/O) chip stack and a second laser source chip on the optical interposer in a configuration such that the second laser source chip is adjacent to the memory I/O chip stack, the memory I/O chip stack including a second photonic IC chip and a memory I/O chip bonded to the second photonic IC chip;
filling in gaps between the memory chips before the sawing the first substrate; and
attaching a fiber array unit to the memory I/O chip stack.
